(19) United States
(12) Patent Application Publication
(10) Pub. No.: US 2008/0246511 A1
(43) Pub. Date: Oct. 9, 2008

(54) Differential Drive Circuit and Electronic Apparatus Incorporating the Same

(76) Inventors: Satoshi Miura, Tokyo (JP); Jun-ichi Okamura, Tokyo (JP); Seiichi Ozawa, Tokyo (JP)

Correspondence Address: COOK ALEX LTD, SUITE 2850, 200 WEST ADAMS STREET, CHICAGO, IL, 60606, US

(21) Appl. No.: 10/585,914

(22) PCT Filed: Apr. 28, 2005
(86) PCT No.: PCT/JP05/08151

§ 371 Date: Jul. 13, 2006

(51) Int. Cl. H03K 19/0175; H03K 3/00

(52) U.S. Cl. 326/83; 327/108

(57) ABSTRACT

A differential driving circuit used for low voltage differential signals and an electronic device incorporating the same are provided wherein no differential amplifiers are used or the number of differential amplifiers are reduced, thereby reducing the circuit area and the current consumption and further solving the problem of oscillation caused by noise, while a high driving performance is achieved. There are included a switch circuit an output circuit and a reference potential generating circuit. The switch circuit, which comprises MOS transistors, receives differential signals and outputs current signals. The output circuit comprises an NMOS transistor, an end of which is connected to the power supply potential of a higher potential side, the other end of which is connected to a node of the switch circuit and which acts as a source follower, and an PMOS transistor, an end of which is connected to the power supply potential of a lower potential side, the other end of which is connected to the other node of the switch circuit and which acts as a source follower. The reference potential generating circuit supplies reference potentials to the respective gates of the PMOS and NMOS transistors. The reference potential generating circuit includes a potential varying means that varies the differential potentials with an offset potential kept constant. Further, there is included an emphasis circuit for the output circuit.

### TECHNICAL FIELD

The present invention relates to a differential drive circuit for an LVDS (Low-Voltage Differential Signals) interface that transmits signals by changing a direction of flow of the electric current in a pair of resistor-terminated differential transmission lines, and an electronic apparatus incorporating the differential drive circuit.

### BACKGROUND OF THE INVENTION

For a differential drive circuit for an LVDS interface, the one described in the patent document 1 as set forth below is known. A drive circuit suggested herein employs a configuration in which by using three differential amplifiers a differential voltage is changed while the offset potential is kept constant. Hence, there are problems that the circuit becomes complicated, increasing the circuit area and the total current consumption, and two differential amplifiers that drive transistors of the final stage are likely to cause oscillation, which is triggered by power supply noise or the like. Furthermore, with a drive circuit capability, the one described in the patent document 2 as set forth below is known. A drive circuit proposed herein is composed of a main drive circuit and a pre-emphasis circuit and both circuits are biased by a current source. Hence, the circuit tries to supply a constant current regardless of changes or variations in load and thus the voltage (V_{SD}) between a source and a drain changes with respect to changes in the load; as a result, the common-mode voltage is not stabilized. Especially in a standby state, the circuit falls in a situation where the trouble of EMI is likely to occur, and thus, there is a problem of noise trouble associated with high-speed drive.

Patent Document 1: Publication of U.S. Pat. No. 6,111,431

Patent Document 2: Publication of U.S. Pat. No. 6,590,432

The present invention is made with a view to solving such problems. An object of the present invention is, therefore, to provide a differential drive circuit for low voltage differential signals, in which, by eliminating differential amplifiers or reducing the number of differential amplifiers, the circuit area and current consumption may be reduced and the problem of oscillation caused by noise may be solved, and by stabilizing the common-mode level, an occurrence of trouble of the EMI may be reduced and a high drive capability is provided, and an electronic apparatus incorporating therein such a circuit.

### SUMMARY OF THE INVENTION

According to a claim 1, there is provided a differential drive circuit for low voltage differential signals, which comprises:

a switching circuit including MOS transistors, and configured to be inputted thereto with differential signals and to output therefrom current signals;

an output circuit including an NMOS transistor connected at its one end to a power supply potential on a high potential side and at its other end to one node of the switching circuit, and operating as a source follower; and a PMOS transistor connected at its one end to a power supply potential on a low potential side and at its other end to the other node of the switching circuit and operating as a source follower; and

a reference potential generating circuit that supplies reference potentials to gates of the NMOS transistor and the PMOS transistor, respectively, wherein

the reference potential generating circuit includes potential variable means for changing a differential potential with an offset potential being kept constant.

According to a claim 2, in the differential drive circuit for low voltage differential signals according to claim 1,

the switching circuit may include a first transistor and a second transistor connected at their one ends to a source of the NMOS transistor, forming a node; a third transistor and a fourth transistor connected at their one ends to a source of the PMOS transistor, forming a node,

a node at which the first transistor and the third transistor are connected at their other ends and a node at which the second transistor and the fourth transistor are connected at their other ends form output terminals of the output circuit, and

a node at which the first transistor and the fourth transistor are connected at their gates and a node at which the second transistor and the third transistor are connected at their gates form input terminals for the differential signals.

According to a claim 3, in the differential drive circuit for low voltage differential signals according to the claim 1, the reference potential generating circuit may include:

a first resistor connected between the power supply potential on the high potential side and the gate of the NMOS transistor;

a second resistor connected between the gate of the NMOS transistor and the gate of the PMOS transistor; and

a third resistor connected between the gate of the PMOS transistor and the power supply potential on the low potential side.

According to a claim 4, in the differential drive circuit for low voltage differential signals according to the claim 3,

the first resistor and the third resistor in the reference potential generating circuit may have an equal resistance value.

According to a claim 5, in the differential drive circuit for low voltage differential signals according to the claim 1,

the reference potential generating circuit may include:

a first circuit group configured to have a plurality of series-connected PMOS transistors and a plurality of series-connected resistors, which are connected in parallel;

a second circuit group configured to have a plurality of series-connected NMOS transistors and a plurality of series-connected resistors, which are connected in parallel; and

a resistor connected between the resistors in the first circuit group and the resistors in the second circuit group, and

the resistors in the first circuit group and the resistors in the second group may be set to an equal resistance value, where the resistance value may be changed by controlling gates of the transistors in the first and the second circuit groups.

According to a claim 6, in the differential drive circuit for low voltage differential signals according to claim 1, the reference potential generating circuit may include:
a first circuit group which further includes:
   a first NMOS transistor connected at its drain to the power supply potential on the high potential side;
   a second NMOS transistor connected at its drain to a source of the first NMOS transistor and at its gate to the power supply potential on the high potential side;
   a third NMOS transistor connected at its source to the power supply potential on the low potential side;
   a fourth NMOS transistor connected at its source to a drain of the third NMOS transistor and at its gate to the power supply potential on the high potential side;
   a first resistor and a second resistor connected between a source of the second NMOS transistor and a drain of the fourth NMOS transistor;
   a first differential amplifier having an output terminal connected to gates of the first NMOS transistor and a fifth NMOS transistor and controlling potentials of the gates, and operating such that a potential of a node at which the first resistor and the second resistor are connected approximates a first reference potential; and
   a current source variable means that controls a current of the third NMOS transistor connected at its source to the power supply potential on the low potential side; and
a second circuit group which further includes:
   the fifth NMOS transistor connected at its drain to the power supply potential on the high potential side;
   a sixth NMOS transistor connected at its drain to a source of the fifth NMOS transistor and at its gate to the power supply potential on the high potential side, and
   a seventh PMOS transistor connected at its drain to the power supply potential on the low potential side;
   an eighth NMOS transistor connected at its source to a source of the seventh PMOS transistor and at its gate to the power supply potential on the high potential side, and
   a third resistor and a fourth resistor connected between a source of the sixth NMOS transistor and a drain of the eighth NMOS transistor; and
   a second differential amplifier having an output terminal connected to a gate of the seventh PMOS transistor and controlling a potential of the gate, and operating such that a potential of a node at which the third resistor and the fourth resistor are connected approximates the first reference potential.

According to a claim 7, in the differential drive circuit for low voltage differential signals according to the claim 6,

resistance values of the first resistor, the second resistor, the third resistor, and the fourth resistor in the reference potential generating circuit may be n/2 (n is a positive integer value) times a resistance value of a terminating resistor connected to output terminals of the output circuit.

According to a claim 8, in the differential drive circuit for low voltage differential signals according to the claim 6,

a size of the first NMOS transistor and that of the fifth NMOS transistor of the reference potential generating circuit may be 1/n (n is a positive integer value) of a size of the NMOS transistor, and

a size of the seventh PMOS transistor may be 1/n (n is a positive integer value) of a size of the PMOS transistor.

According to a claim 9, in the differential drive circuit for low voltage differential signals according to the claim 1,

output terminals of the output circuit may be connected to output terminals of an emphasis circuit,

the emphasis circuit may include a switching circuit for the emphasis circuit including MOS transistors, to which different differential signals are inputted and which output current signals, one node in the switching circuit for the emphasis circuit being connected to a drain of a PMOS transistor, a source of the PMOS transistor being connected to the power supply potential on the high potential side, and a gate of the PMOS transistor being connected to one terminal of a bias power supply for the emphasis circuit, and

the other node of the switching circuit for the emphasis circuit may be connected to a drain of an NMOS transistor, a source of the NMOS transistor may be connected to the power supply potential on the low potential side, and a gate of the NMOS transistor may be connected to other terminal of the bias power supply for the emphasis circuit.

According to a claim 10, in the differential drive circuit for low voltage differential signals according to the claim 9,

the switching circuit for the emphasis circuit may be constituted by the switching circuit according to the claim 2.

According to claim 11, in the differential drive circuit for low voltage differential signals according to the claim 9, the emphasis circuit may be configured in a manner such that:

one node of the switching circuit for the emphasis circuit is connected to a source of an NMOS transistor, a drain of the NMOS transistor is connected to the power supply potential on the high potential side, and a gate of the NMOS transistor is connected to one terminal of a bias power supply for the emphasis circuit; and

the other node of the switching circuit for the emphasis circuit is connected to a source of a PMOS transistor, a drain of the PMOS transistor is connected to the power supply potential on the low potential side, and a gate of the PMOS transistor is connected to the other terminal of the bias power supply for the emphasis circuit.

According to a claim 12, in the differential drive circuit for low voltage differential signals according to the claim 11,

the switching circuit for the emphasis circuit may be constituted by the switching circuit according to the claim 2.

According to a claim 13, there is provided an electronic apparatus, which comprises a differential drive circuit for low voltage differential signals according to any one of the claims 1 through 12.

According to a claim 14, in the electronic apparatus according to the claim 13, the electronic apparatus may be constituted by a mobile terminal.

According to the differential drive circuit for low voltage differential signals of the present invention, it is possible to provide a differential drive circuit for low voltage differential signals by which reduction in the circuit area and current consumption may be achieved so as to solve the problem of oscillation caused by noise, and occurrence of the trouble of EMI may be reduced due to stabilizing of the common-mode level to thereby provide a high drive capability. Also, it is possible to provide an electronic apparatus incorporating therein such a differential drive circuit as described above.

### BRIEF DESCRIPTION OF THE DRAWINGS

FIG. 1 is a circuit block diagram showing a configuration of a differential drive circuit of a first embodiment according to the present invention.

FIG. 2 is a circuit block diagram showing a configuration of a reference potential generating circuit of the first embodiment according to the present invention.

FIG. 3 is a diagram of a reference potential generating circuit having variable resistors, according to the present invention.

FIG. 4 is a diagram of a reference potential generating circuit having a potential variable means, according to the present invention.

FIG. 5 is a diagram of a reference potential generating circuit having another potential variable means, according to the present invention.

FIG. 6 is a circuit block diagram showing a configuration of a differential drive circuit of a second embodiment according to the present invention.

FIG. 7 is a diagram showing input/output signal trains for the differential drive circuit of the second embodiment according to the present invention.

FIG. 8 is a diagram showing other input/output signal trains for the differential drive circuit of the second embodiment according to the present invention.

FIG. 9 is a diagram showing input/output signal trains for a differential drive circuit using another emphasis circuit, according to the present invention.

### DETAILED DESCRIPTION OF THE PRESENTLY PREFERRED EMBODIMENTS

### First Embodiment

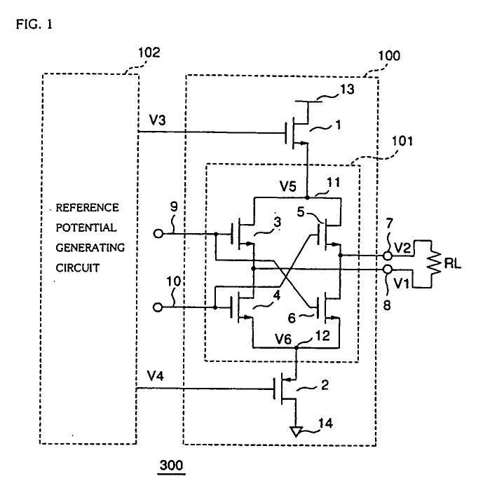

A first embodiment of a differential drive circuit for low voltage differential signals according to the present invention will be described by using FIG. 1. FIG. 1 is a circuit block diagram that describes a configuration of the differential drive circuit for low voltage differential signals of the present invention. A differential drive circuit 300 for low voltage differential signals of the present invention is constituted by an output circuit 100 in compliance with the LVDS interface standard (IEEE P1596, 3) and a reference potential generating circuit 102.

The output circuit 100 is constituted by a switching circuit 101 which receives differential signals inputted to and outputs current signals to a terminating resistor RL; a PMOS transistor 2 which is connected at its one end to a power supply potential 14 on the low potential side and at its other end to a node 12 in the switching circuit 101 and operates as a source follower; and an NMOS transistor 1 which is connected at its one end to a power supply potential 13 on the high potential side and at its other end to a node 11 in the switching circuit 101 and operates as a source follower.

The switching circuit 101 is constituted by NMOS transistors 3 through 6, and drains of the transistors 3 and 5 are commonly connected to a source of the transistor 1, forming the node 11. Sources of the transistors 4 and 6 are commonly connected to a source of the PMOS transistor 2, forming the node 12. A node 8, which is a connection point at which the transistors 3 and 4 are connected in series and a node 7, which is a connection point at which the transistors 5 and 6 are connected in series, form output terminals of the output circuit 100. A node 9, which is a connection point at which the transistors 3 and 6 are commonly connected at their gates and a node 10, which is a connection point at which the transistors 5 and 4 are connected at their gates, form input terminals. The input terminals of the nodes 9 and 10 are inputted thereto with differential signals, which are inverse of each other and are oscillated to the power supply potential on the low potential side and to the power supply potential on the high potential side. The external terminating resistor RL is connected between the nodes 7 and 8.

Provided that the potential of the node 8 is V1 and the potential of the node 7 is V2, the differential potential VOD of outputs can be expressed by VOD=V1−V2. The offset voltage VOC of the outputs can be expressed by VOC=(V1+V2)/2. In this configuration, when reference potentials generated by the reference potential generating circuit 102 are inputted to gates of the NMOS transistor 1 and the PMOS transistor 2, because all transistors have a source follower configuration, the potential of the node 11 and the potential of the node 12 are determined. At this stage, it is indicated that the voltage which is generated by the reference potential generating circuit 102 and applied to the gate of the NMOS transistor 1 is V3, the voltage applied to the gate of the PMOS transistor 2 is V4, the potential of the node 11 is V5, and the potential of the node 12 is V6. Provided that the current flowing through the terminating resistor RL is I1, when I1 is small and the NMOS transistor 1 and the PMOS transistor 2 operate in a saturation region, then I1=βn(V3-V5-Vthn)²/2=βp(V6-V4-Vthp)²/2. Here, βn and βp and Vthn and Vthp are the β values and threshold voltages of the NMOS transistor and PMOS transistor, respectively. Then, formulae of VOD=I1×RL and VOD≈V5−I1×RL/2≈V6+I1×xRL/2 are established. The reference potentials V3 and V4 are determined such that the values VOC and VOD become target values. According to the LVDS standard, the standard value for VOC is 1.2V, the standard value for VOD is 250 mV, and the standard value for RL is 100Ω. An example is provided in which the reference potentials V3 and V4 are determined such that VOC and VOD for the above case become target values. For the simplicity sake, it is assumed that βn=βp=2 and Vthn=Vthp=0.5. From this, a calculation can be done with V3=1.2+0.250/2+1=2.45V and V4=1.2−0.25/2−1=0.12V. Here, attention should be directed to the fact that the β values of the switching transistors 3 to 6 are made to be large so that the ON resistance is sufficiently small. Note that the switching circuit 101 can also be configured as a CMOS circuit, which uses NMOS and PMOS transistors.

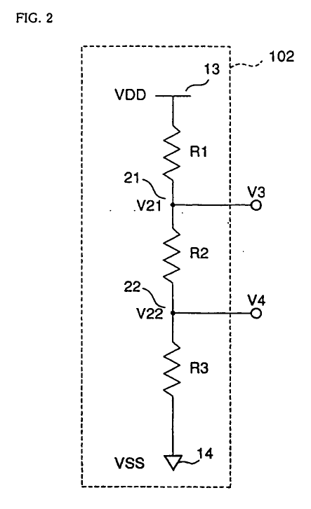

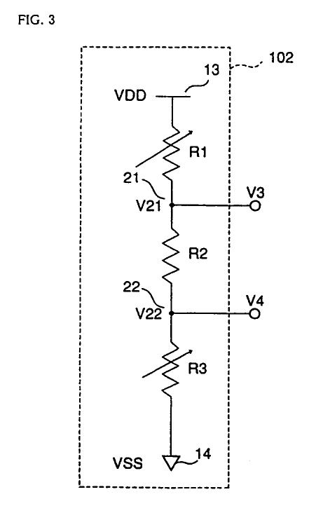

FIG. 2 is a circuit diagram, which describes the embodiment of the reference potential generating circuit 102 according to the present invention. The reference potential generating circuit 102 is constituted by a resistor R1 connected at its one end to a first power supply potential 13 on the high potential side; a resistor R3 connected at its one end to a second power supply potential 14 on the low potential side; and a resistor R2 connected to the R1 and the R3 in series. A connection node 21 between the R1 and the R2 is connected to the gate of the NMOS transistor 1 in the output circuit 100 and supplies a reference potential V3. A connection node 22 between the R2 and the R3 is connected to the gate of the PMOS transistor 2 in the output circuit 100 and supplies a reference potential V4. FIG. 3 is a diagram, which shows a reference potential generating circuit having variable resistors for changing resistors R1 and R3. By changing the resistors R1 and R3, the differential potential is changed with the offset potential being constant. Provided that the potential of a first power supply potential 13 on the high potential side is VDD, the potential of a second power supply potential 14 on the low potential side is VSS, the potential of a node 21 is V21, the potential of a node 22 is V22, and the sum of resistance values R1+R2+R3 is R, V21 and V22 can be expressed by V21=(VDD-VSS)×(R2+R3)/R and V22=(VDD-VSS)×(R3)/R. When the ratio of the gate width to the gate length of each of the NMOS transistor 1 and the PMOS transistor 2 is adjusted in such a manner that currents which flow due to voltages appearing between the respective gates and sources are equal and R3=R1, the offset potential will be defined by the formula of VOC=(VDD+VEE)/2. In this state, the differential voltage VOD moves with the differential potential between the nodes 21 and 22.

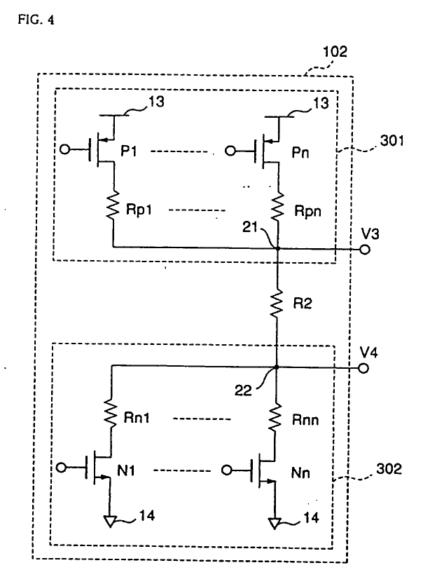

FIG. 4 is a diagram showing a reference potential generating circuit having a potential variable means. The reference potential generating circuit 102 is composed of a first circuit group 301; a second circuit group 302; and a resistor R2 connected in series between the first circuit group 301 and the second circuit group 302. The first circuit group 301 is configured such that a plurality of PMOS transistors P1 to Pn are connected at their source sides to a power supply potential 13 on the high potential side, and a plurality of resistors Rp1 to Rpn are connected at their one ends to the drain sides of the plurality of PMOS transistors P1 to Pn, respectively, and at their other ends to a node 21. The second circuit group 302 is configured such that a plurality of NMOS transistors N1 to Nn are connected at their source sides to a power supply potential 14 on the low potential side, and a plurality of resistors Rn1 to Rnn are connected at their one ends to the drain sides of the plurality of NMOS transistors N1 to Nn, respectively, and at their other ends to a node 22. Each PMOS transistor and resistor in the first circuit group and each NMOS transistor and resistor in the second circuit group are paired with each other, and the resistance values of a combination of the resistors Rp1 and Rn1 and a combination of the resistors Rpn and Rnn are equally set. Here, the combined resistance value of the resistors Rp1 through Rpn is controlled by the gates of the transistors in the first circuit group and the combined resistance value of the resistors Rn1 through Rnn is controlled by the gates of the transistors in the second circuit group, whereby VOD can be changed with VOC being constant.

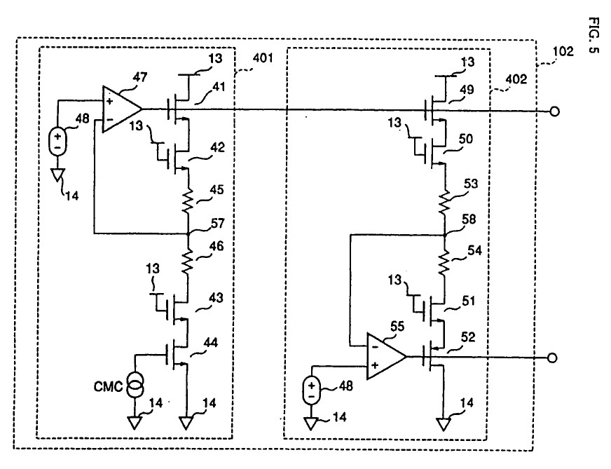

FIG. 5 is a diagram showing a reference potential generating circuit having another potential variable means. A reference potential generating circuit 102 includes a first circuit group 401 and a second circuit group 402. The first circuit group 401 is composed of an NMOS transistor 41 connected at its drain to a power supply potential 13 on the high potential side and having a gate width which is 1/n of that of the NMOS transistor 1 in FIG. 1; an NMOS transistor 42 connected at its drain to a source of the NMOS transistor 41 and at its gate to the power supply potential 13 and having a gate width which is 1/n of that of the MOS transistors 3 and 5; resistors 45 and 46 connected in series to a source of the NMOS transistor 42 and having a resistance value which is n/2 of that of the terminating resistor RL; an NMOS transistor 43 connected at its drain to the other terminal of the resistor 46 and at its gate to the power supply potential 13 and having a gate width which is 1/n of that of the MOS transistors 4 and 6; an NMOS transistor 44 connected at its drain to a source of the NMOS transistor 43, at its source to a power supply potential 14 on the low potential side, and at its gate to a current mirror circuit CMC; and a differential amplifier 47 having an non-inverting input terminal to which is connected a first reference potential 48 that controls the gate potentials of the NMOS transistor 41 and an NMOS transistor 49. An inverting input terminal of the differential amplifier 47 is connected to a connection point between the resistors 45 and 46.

The second circuit group 402 is constituted by an NMOS transistor 49 connected at its drain to the power supply potential 13 on the high potential side and having a gate width which is 1/n of that of the NMOS transistor 1 in FIG. 1; an NMOS transistor 50 connected at its drain to a source of the NMOS transistor 49 and at its gate to the power supply potential 13 and having a gate width which is 1/n of that of the MOS transistors 4 and 6; resistors 53 and 54 connected in series to a source of the NMOS transistor 50 and having a resistance value which is n/2 of that of the terminating resistor RL; an NMOS transistor 51 connected at its drain to the other terminal of the resistor 54 and at its gate to the power supply potential 13 and having a gate width which is 1/n of that of the MOS transistors 4 and 6; a PMOS transistor 52 connected at its source to a source of the NMOS transistor 51 and at its drain to the power supply potential 14 on the low potential side and having a gate width which is 1/n of that of the PMOS transistor 2; and a differential amplifier 55 having an non-inverting input terminal to which is connected a reference potential 56 that controls the gate potential of the PMOS transistor 52. An inverting input terminal of the differential amplifier 55 is connected to a connection point between the resistors 53 and 54.

The differential amplifier 47 controls the potential of a node at which the resistors 45 and 46 are connected, such that the potential approximates the reference potential 48 connected to the differential amplifier 47. The differential amplifier 55 controls the potential of a node at which the resistors 53 and 54 are connected, such that the potential approximates the reference potential 56 connected to the differential amplifier 55. The differential potential of outputs is the potential difference between the nodes 8 and 7 and the current I flowing through the terminating resistor RL, and thus is represented by VOD=I×RL. Here, a current of I/n flows through the NMOS transistors 41 and 49 in the reference potential generating circuit 102. The potential difference appearing between a connection node of the NMOS transistor 42 and the resistor 45 and a connection node of the resistor 46 and the NMOS transistor 43 and the potential difference appearing between a connection node of the NMOS transistor 50 and the resistor 53 and a connection node of the resistor 54 and the NMOS transistor 51 are represented by I/n×(nRL/2+nRL/2)=I×RL. The current I/n flowing through the NMOS transistor 44 is determined such that the value of I×RL becomes a target value. The offset potential VOC of the outputs can be expressed, using the potential V1 of the node 8 and the potential V2 of the node 7, by the formula of VOC=(V1+V2)/2. The offset potential VOC moves with the potentials of the node 57 at which the resistors 45 and 46 are connected and the node 58 at which the resistors 53 and 54 are connected. Therefore, the offset potential VOC is determined by setting the reference potentials 48 and 56 such that the potentials of the nodes 57 and 58 become target values. As such, the differential voltage VOD can be changed with the offset potential VOC being kept constant.

As described above, in the present invention, since the voltage V3 supplied to the gate of the NMOS transistor 1 and the voltage V4 supplied to the gate of the PMOS transistor 2 can be supplied without the need for a differential amplifier, the power consumption is small and the circuit area does not increase. Furthermore, since control can be performed without using a differential amplifier, a configuration resistant to oscillation caused by power supply noise is obtained and the load drive capability is also high.

### Second Embodiment

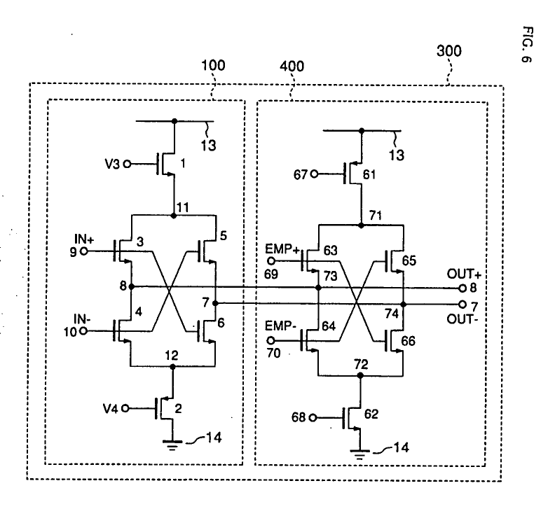

A second embodiment of a differential drive circuit for low voltage differential signals according to the present invention will be described by using FIG. 6. FIG. 6 is a circuit block diagram that describes a configuration of a high output differential drive circuit of the present invention. A differential drive circuit 300 for low voltage differential signals of the present invention is constituted by an output circuit 100, an emphasis circuit 300, and a bias circuit (not shown) for the circuits, for example, a reference potential generating circuit 102.

The output circuit 100 is a circuit described in FIG. 1. In the emphasis circuit 400, a drain of a PMOS transistor 61 is connected to a node 71 in a switching circuit for the emphasis circuit composed of MOS transistors, to which are inputted differential signals different from those inputted to the output circuit 100 and which outputs current signals. A source of the PMOS transistor 61 is connected to a power supply on the high potential side 13, and furthermore, a gate of the PMOS transistor 61 is connected to one terminal 67 of a bias power supply (not shown) for the emphasis circuit. In addition, a drain of an NMOS transistor 62 is connected to a node 72 in the switching circuit for the emphasis circuit.

A source of the NMOS transistor 62 is connected to a power supply 14 on the low potential side, and furthermore, a gate of the NMOS transistor 62 is connected to the other terminal 68 of the bias power supply for the emphasis circuit.

The switching circuit for the emphasis circuit is the same circuit as the switching circuit 101 of FIG. 1. The NMOS transistors 63 and 65 are connected to each other at their drains, forming the node 71 and the NMOS transistors 64 and 66 are connected to each other at their sources, forming the node 72. The NMOS transistors 63 and 64 and the NMOS transistors 65 and 66 are connected to each other at their sources and drains, forming nodes 73 and 74, respectively. The gates of the NMOS transistors 63 and 66 are connected to a differential signal output terminal on the positive side 69 and the gates of the NMOS transistors 64 and 65 are connected to a differential output terminal on the negative side 70. A node 8 in the output circuit 100 and the node 73 in the emphasis circuit 400, and a node 7 in the output circuit 100 and the node 74 in the emphasis circuit 400 are connected to each other, forming output terminals 8 and 7 of the high output differential drive circuit 300, respectively.

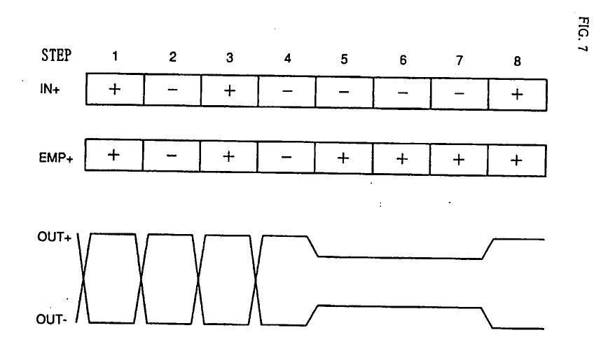

FIG. 7 is a diagram showing, by steps, input/output signal trains for output signals from the high output differential drive circuit 300, which emerge with respect to a positive side of a differential input signal inputted to the output circuit 100 and a positive side of a differential input signal inputted to the emphasis circuit 400.

At step 1 in FIG. 7, when the plus side of the differential input signal inputted to the output circuit 100 and the plus side of the differential input signal inputted to the emphasis circuit 400 in FIG. 6 both have a high potential, the negative sides of their corresponding differential input signals have a low potential. That is, the NMOS transistors 3 and 6 on the drive circuit side are in a switched-on state and the NMOS transistors 4 and 5 are in a switched-off state. Similarly, the NMOS transistors 63 and 66 in the emphasis circuit 400 are in a switched-on state and the NMOS transistors 64 and 65 are in a switched-off state.

On the other hand, regardless of the steps in FIG. 7, the gates of the NMOS transistor 1 and the PMOS transistor 2 in the output circuit 100 of FIG. 6 are activated by bias voltages, respectively, from the reference potential generating circuit 102, which is a bias power supply for the drive circuit, and operate as source followers. Thus, a constant voltage that is determined by bias voltages of the reference potential generating circuit 102 is generated at the nodes 11 and 12 as an output of a voltage drive. The PMOS transistor 61 and the NMOS transistor 62 in the emphasis circuit 400 are activated through the bias power supply terminals 67 and 68 for the emphasis circuit and by a current source realized by a current mirror or the like. Therefore, it operates as a current-driven circuit which is determined by the current of a bias.

Now, at step 1, the NMOS transistors 3 and 6 in the switching circuit of the output circuit 100 are ON and the NMOS transistors 63 and 66 in the switching circuit of the emphasis circuit 400 are ON, and thus, the potential of the output terminal 8 of the differential drive circuit 300 is at a high level and the potential of the output terminal 7 is at a low level. The high level rapidly rises by the voltage drive of the output circuit 100 and further has a drive capability of supplying a current by the current drive of the emphasis circuit 400 and absorbing stray capacitance across the long signal line load. Similarly, the low level rapidly drops by the voltage drive of the output circuit 100 and further has a drive capability of drawing the charge of stray capacitance across the long signal line load by the current drive of the emphasis circuit 300. Since the emphasis circuit 400 is current driven, the voltage V_{SD} between the source and drain of each of the PMOS transistor 61 and the NMOS transistor 62 automatically changes according to an applied load, and when the drive pulse amplitude of the differential drive circuit 300 is increased, it has an equivalent capability and thus can perform high-speed drive even when the applied load is increased.

At step 2, since the differential signal input to the switching circuit of each of the output circuit 100 and the emphasis circuit 400 is inverted, the operations of the switching circuits are inverted and accordingly the potentials of the output terminals 7 and 8 of the differential drive circuit 300 are also inverted. At steps 3 and 4, these operations are repeated.

At steps 5 to 7, when the positive side of the differential input signal inputted to the output circuit 100 in FIG. 6 has a low potential and the positive side of the differential input signal inputted to the emphasis circuit 400 has a high potential, the negative sides of their corresponding differential input signals have potentials which are inverse of the potentials of their corresponding signals. That is, the NMOS transistors 3 and 6 on the drive circuit side are in a switched-off state and the NMOS transistors 4 and 5 are in a switched-on state. Similarly, the NMOS transistors 63 and 66 in the emphasis circuit 400 are in a switched-on state and the NMOS transistors 64 and 65 are in a switched-off state.

Now, at steps 5 to 7, the NMOS transistors 3 and 6 in the switching circuit of the output circuit 100 are OFF and the NMOS transistors 63 and 66 in the switching circuit of the emphasis circuit 400 are ON. Thus, the potential of the output terminal 8 of the differential drive circuit 300 has a value obtained by increasing the voltage which is determined by the voltage drive of the PMOS transistor 2 in the output circuit 100, by an amount equal to the current flowing through the PMOS transistor 61 in the emphasis circuit 400. On the other hand, the potential of the output terminal 7 has a value obtained by reducing the voltage which is determined by the voltage drive and is the voltage of the NMOS transistor 1 in the output circuit 100, by an amount equal to the current flowing through the NMOS transistor 62 in the emphasis circuit 400. Accordingly, as shown by output waveforms in FIG. 7, the amplitude is reduced and a stable potential is set and thus a stable common-mode voltage can be obtained, making it possible to prevent trouble of EMI.

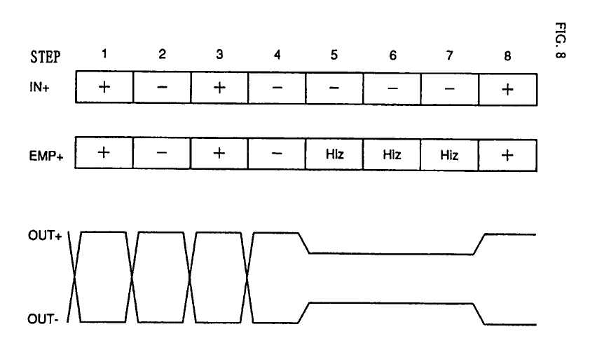

FIG. 8 is a diagram showing other input/output signal trains. Now, at step 1, the NMOS transistors 3 and 6 in the switching circuit of the output circuit 100 are ON and the NMOS transistors 63 and 66 in the switching circuit of the emphasis circuit 400 are ON, and thus, the potential of the output terminal 8 of the differential drive circuit 300 is at a high level and the potential of the output terminal 7 is at a low level. The high level rapidly rises by the voltage drive of the output circuit 100 and furthermore a current is supplied by the current drive of the emphasis circuit 400; similarly, the low level rapidly drops by the voltage drive of the output circuit 100 and furthermore, a current is supplied by the current drive of the emphasis circuit 300, whereby the amplitude is increased more than that at normal time. By this, even when the signal lines are long and the high-frequency components of signals are attenuated, since the amplitude is increased in advance, a certain signal quality can be maintained. In addition, since the emphasis circuit 400 is current driven, when the output current is I and the switch resistance of a group of switching transistors for the drive circuit is R_{SW}, by the current drive, the amplitude can be increased by an amount equal to R_{SW}I.

At step 2, since the differential signal input to the switching circuit of each of the output circuit 100 and the emphasis circuit 400 is inverted, the operations of the switching circuits are inverted and accordingly, the potentials of the output terminals 7 and 8 of the differential drive circuit 300 are also inverted. At steps 3 and 4, these operations are repeated.

At steps 5 to 7, all differential input signals inputted to the output circuit 100 of FIG. 6 are low. That is, the NMOS transistors 3 and 6 on the drive circuit side are in a switched-off state and the NMOS transistors 4 and 5 are in a switched-on state. Similarly, the NMOS transistors 63 to 66 in the emphasis circuit 400 are in a switched-off state.

Now, at steps 5 to 7, the NMOS transistors 3 and 6 in the switching circuit of the output circuit 100 are OFF and the NMOS transistors 63 to 66 in the switching circuit of the emphasis circuit 400 are OFF. Therefore, the potential of the output terminal 8 of the differential drive circuit 300 is determined only by the output circuit 100 and thus the amplitude does not increase. When the emphasis circuit is ON, as compared with when it is OFF, the high level is increased by an amount equal to R_{SW}I and the low level is reduced by an amount equal to R_{SW}I. Accordingly, the common-mode voltage does not change in either case and thus a stable common-mode voltage can be obtained, making it possible to prevent trouble of EMI.

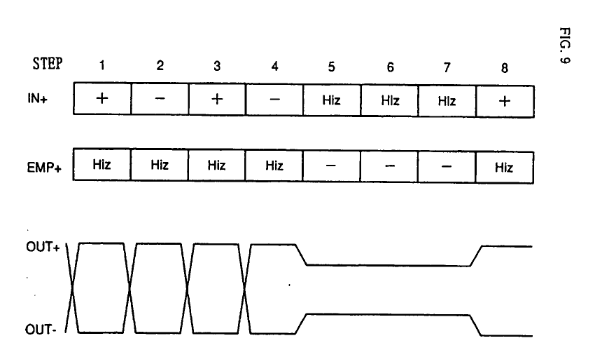

FIG. 9 is a diagram showing input/output signal trains for a third embodiment in which the PMOS transistor 61 and the NMOS transistor 62 in the emphasis circuit 400 of FIG. 6 are respectively replaced with transistors of the same type as the NMOS transistor 1 and the PMOS transistor 2 in the output circuit 100, and made to serve as source followers.

At steps 1 to 4 in FIG. 9, a differential input signal inputted to the emphasis circuit 400 is high impedance. Thus, the potentials of the respective output terminals 7 and 8 of the differential drive circuit 300 are determined by the drive voltage of the output circuit 100. In this case, a unique circuit design is made possible in which the output circuit 100 is separated from the emphasis circuit 400 so as to obtain high potential outputs according to the circuit load. At steps 5 to 7, the differential input signal inputted to the output circuit 100 is high impedance. Thus, the potentials of the output terminals 7 and 8 of the differential drive circuit 300 are determined by the drive voltage of the emphasis circuit 400. In this case too, similarly, it is possible to set a constant voltage in a standby state according to the circuit load by separating the emphasis circuit 400 from the output circuit 100. The operation can be read as in the case of FIG. 7.

As described above, in the present invention, by an emphasis means of increasing the amplitude at a transmitting end by current injection the drive capability of outputs is improved, and by voltage drive the common-mode level is stabilized, whereby the occurrence of trouble of EMI can be reduced; therefore, although the circuit is used for low voltage differential signals, high-speed long-distance drive is made possible.

A differential drive circuit for low voltage differential signals of the present invention can be applied not only to an LVDS interface but also to the differential drive circuit itself.

1. A differential drive circuit for low voltage differential signals, comprising:
a switching circuit composed of MOS transistors, and configured to be inputted thereto with differential signals and to output current signals;
an output circuit including an NMOS transistor connected at its one end to a power supply potential on a high potential side and at its other end to one node in the switching circuit, and operating as a source follower; and a PMOS transistor connected at its one end to a power supply potential on a low potential side and at its other end to other node in the switching circuit and operating as a source follower; and
a reference potential generating circuit that supplies reference potentials to gates of the NMOS transistor and the PMOS transistor, respectively, wherein
the reference potential generating circuit includes potential variable means for changing a differential potential with an offset potential being kept constant.

2. The differential drive circuit for low voltage differential signals according to claim 1, wherein
the switching circuit includes: a first transistor and a second transistor connected at their one ends to a source of the NMOS transistor, forming a node; and a third transistor and a fourth transistor connected at their one ends to a source of the PMOS transistor, forming a node,
a node at which the first transistor and the third transistor are connected at their other ends and a node at which the second transistor and the fourth transistor are connected at their other ends form output terminals of the output circuit, and
a node at which the first transistor and the fourth transistor are connected at their gates and a node at which the second transistor and the third transistor are connected at their gates form input terminals for the differential signals.

3. The differential drive circuit for low voltage differential signals according to claim 1, wherein the reference potential generating circuit includes:
a first resistor connected between the power supply potential on the high potential side and the gate of the NMOS transistor;
a second resistor connected between the gate of the NMOS transistor and the gate of the PMOS transistor; and
a third resistor connected between the gate of the PMOS transistor and the power supply potential on the low potential side.

4. The differential drive circuit for low voltage differential signals according to claim 3, wherein the first resistor and the third resistor in the reference potential generating circuit have an equal resistance value.

5. The differential drive circuit for low voltage differential signals according to claim 1, wherein
the reference potential generating circuit includes:
a first circuit group composed of a plurality of PMOS transistors connected in series and a plurality of resistors connected in series, which are connected in parallel;
a second circuit group composed of a plurality of NMOS transistors connected in series and a plurality of resistors connected in series, which are connected in parallel; and
a resistor connected between the resistors in the first circuit group and the resistors in the second circuit group, and wherein the resistors in the first circuit group and the resistors in the second group are set to an equal resistance value, the resistance value being changeable by controlling gates of the transistors in the first and the second circuit groups.

6. The differential drive circuit for low voltage differential signals according to claim 1, wherein the reference potential generating circuit includes:
a first circuit group further including:
a first NMOS transistor connected at its drain to the power supply potential on the high potential side;
a second NMOS transistor connected at its drain to a source of the first NMOS transistor and at its gate to the power supply potential on the high potential side;
a third NMOS transistor connected at its source to the power supply potential on the low potential side;
a fourth NMOS transistor connected at its source to a drain of the third NMOS transistor and at its gate to the power supply potential on the high potential side;
a first resistor and a second resistor connected between a source of the second NMOS transistor and a drain of the fourth NMOS transistor;
a first differential amplifier having an output terminal connected to gates of the first NMOS transistor and a fifth NMOS transistor and controlling potentials of the gates, and operating such that a potential of a node at which the first resistor and the second resistor are connected approximates a first reference potential; and
a current source variable means that controls a current of the third NMOS transistor connected at its source to the power supply potential on the low potential side; and
a second circuit group further including:
the fifth NMOS transistor connected at its drain to the power supply potential on the high potential side;
a sixth NMOS transistor connected at its drain to a source of the fifth NMOS transistor and at its gate to the power supply potential on the high potential side, and a seventh PMOS transistor connected at its drain to the power supply potential on the low potential side;
an eighth NMOS transistor connected at its source to a source of the seventh PMOS transistor and at its gate to the power supply potential on the high potential side, and a third resistor and a fourth resistor connected between a source of the sixth NMOS transistor and a drain of the eighth NMOS transistor; and
a second differential amplifier having an output terminal connected to a gate of the seventh PMOS transistor and controlling a potential of the gate, and operating such that a potential of a node at which the third resistor and the fourth resistor are connected approximates the first reference potential.

7. The differential drive circuit for low voltage differential signals according to claim 6, wherein resistance values of the first resistor, the second resistor, the third resistor, and the fourth resistor in the reference potential generating circuit are n/2 (n is a positive integer value) times a resistance value of a terminating resistor connected to output terminals of the output circuit.

8. The differential drive circuit for low voltage differential signals according to claim 6, wherein
a size of the first NMOS transistor and that of the fifth NMOS transistor in the reference potential generating circuit are 1/n (n is a positive integer value) of a size of the NMOS transistor, respectively, and
a size of the seventh PMOS transistor is 1/n (n is a positive integer value) of a size of the PMOS transistor.

9. The differential drive circuit for low voltage differential signals according to claim 1,
wherein output terminals of the output circuit are connected to output terminals of an emphasis circuit,
wherein the emphasis circuit includes a switching circuit for the emphasis circuit constituted by MOS transistors, which are inputted thereto with different differential signals, and output current signals, one node in the switching circuit for the emphasis circuit being connected to a drain of a PMOS transistor, a source of the PMOS transistor connected to the power supply potential on the high potential side, and a gate of the PMOS transistor connected to one terminal of a bias power supply for the emphasis circuit, and
wherein the other node in the switching circuit for the emphasis circuit is connected to a drain of an NMOS transistor, a source of the NMOS transistor being connected to the power supply potential on the low potential side, and a gate of the NMOS transistor being connected to the other terminal of the bias power supply for the emphasis circuit.

10. The differential drive circuit for low voltage differential signals according to claim 9, wherein the switching circuit for the emphasis circuit is the switching circuit according to claim 2.

11. The differential drive circuit for low voltage differential signals according to claim 9, wherein the emphasis circuit is configured in such a manner that:
one node in the switching circuit for the emphasis circuit is connected to a source of an NMOS transistor, a drain of the NMOS transistor is connected to the power supply potential on the high potential side, and a gate of the NMOS transistor is connected to one terminal of a bias power supply for the emphasis circuit; and
the other node in the switching circuit for the emphasis circuit is connected to a source of a PMOS transistor, a drain of the PMOS transistor is connected to the power supply potential on the low potential side, and a gate of the PMOS transistor is connected to other terminal of the bias power supply for the emphasis circuit.

12. The differential drive circuit for low voltage differential signals according to claim 11, wherein the switching circuit for the emphasis circuit is the switching circuit according to claim 2.

13. An electronic apparatus comprising a differential drive circuit for low voltage differential signals according to any one of claims 1 through 12.

14. The electronic apparatus according to claim 13, wherein the electronic apparatus is constituted by a mobile terminal.
